(19) United States
(12) Patent Application Publication
(10) Pub. No.: US 2014/0120401 A1
(43) Pub. Date: May 1, 2014

(54) CONNECTING STRUCTURE BETWEEN CIRCUIT BOARDS AND BATTERY PACK HAVING THE SAME

(71) Applicant: SAMSUNG SDI CO., LTD., Yongin-si (KR)

(72) Inventors: Kyungjae Shin, Yongin-si (KR); Kiwoong Kim, Yongin-si (KR)

(73) Assignee: Samsung SDI Co., Ltd., Yongin-si (KR)

(21) Appl. No.: 13/774,768

(22) Filed: Feb. 22, 2013

Related U.S. Application Data
(60) Provisional application No. 61/720,097, filed on Oct. 30, 2012.

(51) Int. Cl. H01M 10/42; H01R 43/02; H05K 1/11

(52) U.S. Cl. CPC H01M 10/425; H05K 1/118; H01R 43/0256
USPC 429/123; 174/261; 29/879

(57) ABSTRACT

A connecting structure between circuit boards and a battery pack having the same. A hot bar does not make a direct contact with a circuit pattern of a flexible printed circuit board while soldering the flexible printed circuit board to a rigid printed circuit board, thereby preventing the damage to the circuit pattern and preventing electric short between a plurality of the circuit patterns due to the solder. During a soldering process, a base insulating layer having glass transition temperature (Tg) higher than a reflow temperature of the solder is arranged between the circuit pattern and the hot bar, the base insulating layer being perforated by a plurality of apertures to allow heat from the hot bar to more efficiently reach the circuit pattern and the solder. In addition, the circuit pattern covers the apertures, so that solder is unable to reach the hot iron.

### CLAIM OF PRIORITY

This application makes reference to, incorporates the same herein, and claims all benefits accruing under 35 U.S.C. §119 from my application earlier filed in the U.S. Patent and Trademark Office on Oct. 30, 2012 and there duly assigned Ser. No. 61/720,097.

### BACKGROUND OF THE INVENTION

1. Field of the Invention

Embodiments relate to a connecting structure between circuit boards and a battery pack having the same.

2. Description of the Related Art

Generally, a battery pack may include a battery cell, a rigid printed circuit board and a flexible printed circuit board. Onto the rigid printed circuit board, the flexible printed circuit board may be soldered by means of soldering iron, a hot bar, etc.

For example, solder may be coated on the circuit patterns of a rigid printed circuit board, and the circuit patterns of a flexible printed circuit board may be attached onto the solder. Then, a hot bar pressurizes and heats the flexible printed circuit board toward the rigid printed circuit board. The solder may reflow to make an electric connection between the circuit patterns of the rigid printed circuit board and the circuit patterns of the flexible printed circuit board. Then, the solder of a liquid state may be cured to a solid state in a subsequent cooling process.

However, according to the common soldering method, the circuit patterns of the flexible printed circuit board may be extruded and extended outward in a cantilever manner. In this case, the circuit patterns may make a direct contact with the hot bar and the circuit patterns may be damaged easily. In addition, the liquid state solder may make a contact with the hot bar, and a removing process of the solder from the hot bar may be required.

In addition, the hot bar may make a direct contact with the circuit patterns of the flexible printed circuit board and the solder. In this case, the solder in the liquid state may make a contact with the hot bar, and an electric short between a plurality of the circuit patterns may be frequently generated due to the solder in the liquid state.

Further, since the circuit patterns of the flexible printed circuit board may be extruded and extended outward by a certain length, a process of coating the circuit patterns with an insulating epoxy material may be additionally conducted to protect the circuit patterns from external environment.

### SUMMARY OF THE INVENTION

According to exemplary embodiments, a connecting structure between circuit boards, in which a hot bar does not make a direct contact with a circuit pattern of a flexible printed circuit board while soldering the flexible printed circuit board onto a rigid printed circuit board, thereby preventing the damage of the circuit pattern, and preventing an electric short between a plurality of the circuit patterns by solder, and a battery pack having the same are provided.

According to exemplary embodiments, a connecting structure between circuit boards, in which circuit patterns of a flexible printed circuit board making a contact with a hot bar is covered with an insulating layer, thereby improving the strength of the circuit patterns and possibly omitting an epoxy coating process, and a battery pack having the same are provided.

According to exemplary embodiments, a connecting structure between circuit boards, in which at least one aperture is formed in an insulating layer making contact with a hot bar, thereby accomplishing soldering without increasing the temperature of the hot bar and without decreasing the lifetime of the hot bar, and a battery pack having the same are provided.

According to one aspect of the present invention, there is provided a battery pack that includes a first printed circuit board including a first circuit pattern having first major surface opposite a second major surface, the second major surface being covered by a first base insulating layer and a portion of the first major surface being covered by a first cover insulating layer, the first base insulating layer being perforated by at least one aperture, each of the at least one aperture being entirely covered by the first circuit pattern, a second printed circuit board having one side attached to a first end of the first printed circuit board by a conductive connecting member, a plurality of battery cells arranged on the second printed circuit board, the plurality of battery cells being electrically interconnected together, a pack case enclosing the first printed circuit board, the second printed circuit board and the battery cells and pack terminals arranged on an outside of the pack case and being attached to a second and opposite end of the first printed circuit board.

The first base insulating layer may have a glass transition temperature (Tg) that is greater than a reflow temperature of the conductive connecting member. The first base insulating layer may include an electrically insulating material having a glass transition temperature (Tg) of at least 300° C. The conductive connecting member may be a solder having a reflow temperature of less than 300° C. The conductive connecting member may include an anisotropic conductive film (ACF) or a Z-axis film (ZAF). The first printed circuit board may be a flexible printed circuit board that can bend freely as compared to the second printed circuit board. The battery pack may also include a second circuit pattern arranged on the second printed circuit board, the second circuit pattern may be aligned with the first circuit pattern. A width of the second circuit pattern may be greater than a width of the first circuit pattern. The first end of the first printed circuit board that is attached to the second printed circuit board may be absent of the first cover insulating layer.

According to another aspect of the present invention, there is provided a printed circuit board (PCB) that includes a base insulating layer perforated by at least one aperture, a circuit pattern arranged on the base insulating layer and covering each of the at least one aperture and a cover insulating layer arranged on the circuit pattern and on the base insulating film. A terminal end of the PCB may be absent of the cover insulating layer. The base insulating layer may include polyimide or polyethylene terephthalate (PET). The cover insulating layer may include polyimide or polyethylene terephthalate (PET). The printed circuit board may be a flexible printed circuit board that can bend freely. The base insulating layer may include a material having a glass transition temperature (Tg) of at least 300° C. and a melting point (Tm) of at least 500° C. The cover insulating layer may include a material having a glass transition temperature (Tg) of at least 70° C. and a melting point (Tm) of at least 270° C. Each of the at least one aperture may be elongated in a lengthwise direction of the circuit pattern. Each of the at least one aperture may instead be elongated in a widthwise direction of the circuit pattern.

According to still another aspect of the present invention, there is provided a method of connecting a first printed circuit board to a second printed circuit board, including preparing the first printed circuit board by arranging a first cover insulating layer onto a portion of a first surface of a first circuit pattern, and arranging a first base insulating layer onto a second and opposite surface of the first circuit pattern, the first base insulating layer being perforated by at least one aperture, the first circuit pattern covering each of the at least one aperture, preparing the second printed circuit board by arranging a second circuit pattern onto a second base insulating layer, applying a conductive connecting member onto the second circuit pattern by screen printing, aligning the first circuit pattern with the second circuit pattern by mounting a terminal end portion of the first printed circuit board onto one side of the second printed circuit board, reflowing said conductive connecting member by placing a hot iron onto a portion of the first base insulating layer corresponding to the terminal end portion of the first printed circuit board, the at least one aperture to rapidly and efficiently transmit heat from the hot iron to the first circuit pattern and to the conductive connecting member and allowing the conductive connecting member to cure by separating the hot iron from the first base insulating layer. The first circuit pattern may be spaced apart from the hot iron by the first base insulating layer upon said placing of the hot iron onto the portion of the first base insulating layer.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1A illustrates a circuit diagram of a common battery pack;

FIG. 1B illustrates a schematic diagram of the common battery pack;

FIG. 1C illustrates a plan view of a connecting structure between circuit boards according to an embodiment of the present invention;

FIG. 2A illustrates a plan view of a flexible circuit board according to an embodiment of the present invention;

FIG. 2B illustrates a bottom view of FIG. 2A;

FIG. 2C illustrates a cross-sectional view of FIG. 2A cut along a line 2c-2c;

FIG. 2D illustrates a cross-sectional view of FIG. 2A cut along a line 2d-2d;

FIG. 3A illustrates a partially enlarged plan view on the connecting structure between circuit boards according to an embodiment of the present invention;

FIG. 3B illustrates a cross-sectional view of FIG. 3A cut along a line 3b-3b;

FIG. 3C illustrates a cross-sectional view of FIG. 3A cut along a line 3c-3d;

FIG. 4A illustrates a cross-sectional view of the connecting structure between circuit boards according to another embodiment of the present invention having a cut line corresponding to that of 3b-3b of FIG. 3a;

FIG. 4B illustrate cross-sectional views of the connecting structure between circuit boards according to the another embodiment of the present invention having a cut line corresponding to that of 3c-3c of FIG. 3a;

FIG. 5 illustrates a partially enlarged plan view on the connecting structure between circuit boards according to a first variation in the aperture structure from that of FIG. 3a;

FIG. 6 illustrates a partially enlarged plan view on the connecting structure between circuit boards according to a second variation in the aperture structure from that of FIG. 3a;

FIG. 7 illustrates a partially enlarged plan view on the connecting structure between circuit boards according to a third variation in the aperture structure from that of FIG. 3a;

FIG. 8 illustrates a partially enlarged plan view on the connecting structure between circuit boards according to a fourth variation in the aperture structure from that of FIG. 3a; and

FIGS. 9A and 9B illustrate a schematic diagram for explaining a connecting method of circuit boards according to an embodiment of the present invention.

### DETAILED DESCRIPTION OF THE INVENTION

Example embodiments will now be described more fully hereinafter with reference to the accompanying drawings.

The present inventive concept may, however, be embodied in different forms and should not be construed as limited to the embodiments set forth herein. Rather, these embodiments are provided so that this disclosure will be thorough and complete, and will fully convey the scope of the invention to those skilled in the art.

In the drawings, the sizes and relative sizes of layers may be exaggerated for the convenience of description and clarity. Like numerals refer to like elements throughout. As used herein, the term “and/or” includes any and all combinations of one or more of the associated listed items.

The terminology used herein is for the purpose of describing particular example embodiments only and is not intended to be limiting of the present inventive concept. As used herein, the singular forms are intended to include the plural forms as well, unless the context clearly indicates otherwise. It will be further understood that the terms “comprise” and/or “comprising,” when used in this specification, specify the presence of stated features, integers, steps, operations, elements, and/or groups, but do not preclude the presence or addition of one or more other features, integers, steps, operations, elements, components, and/or groups thereof.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

The connecting structure between circuit boards in accordance with exemplary embodiments may be used in a hard disk drive (HDD), a solid state drive (SDD), a camera module, a liquid crystal display (LCD) and a plasma display panel (PDP) as well as a battery pack, which will be described below. Accordingly, exemplary embodiments may not be limited to the use of the battery pack.

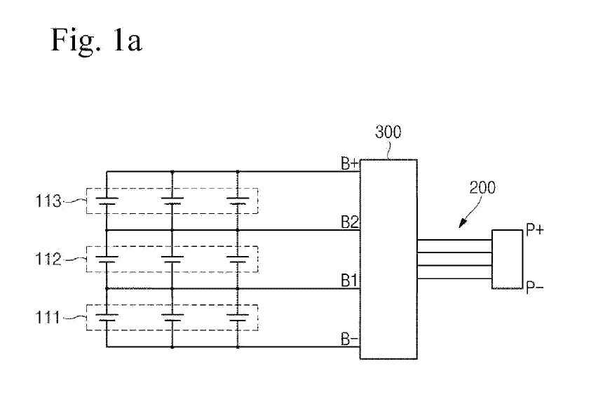

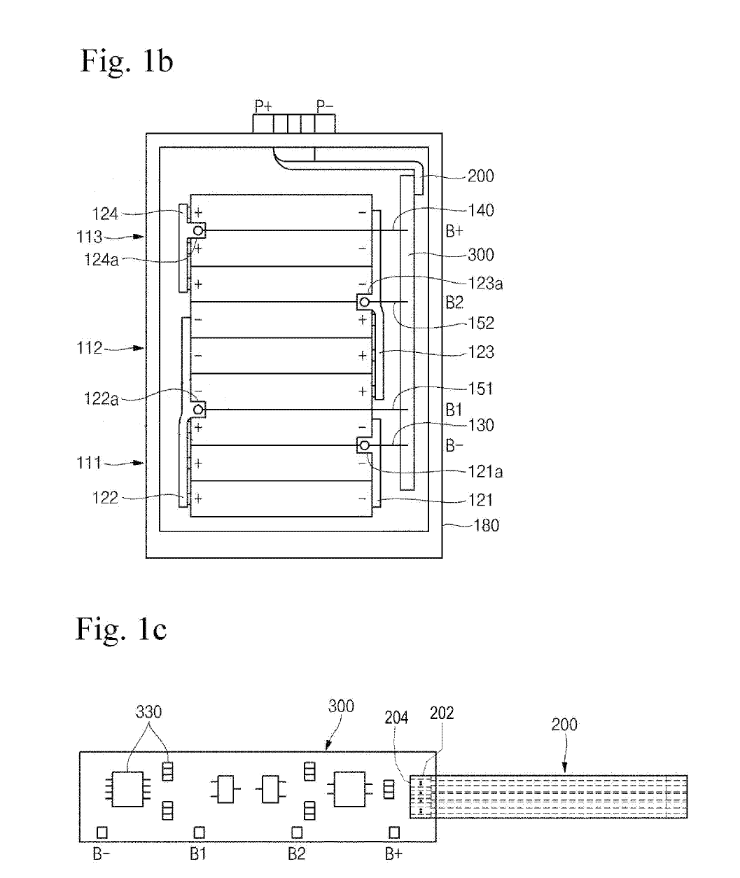

Turning now to FIGS. 1A through 1C, FIG. 1A illustrates a circuit diagram of a common battery pack, FIG. 1B illustrates a schematic diagram of a common battery pack, and FIG. 1C illustrates a plan view of a connecting structure between circuit boards according to an embodiment of the present invention.

As illustrated in FIGS. 1A to 1C, battery pack 100 in accordance with exemplary embodiments includes a plurality of battery cells 111, 112 and 113, a plurality of conductive plates 121, 122, 123 and 124 for connecting each of the battery cells 111, 112 and 113, a wire for minimum power supply 130, a wire for maximum power supply 140, a plurality of sensing wires 151 and 152, a rigid printed circuit board 300 and a flexible printed circuit board 200.

The plurality of the battery cells 111, 112 and 113 are connected in series and/or in parallel. Particularly, the plurality of the battery cells 111, 112 and 113 include three of first battery cells 111 connected to each other in parallel, three of second battery cells 112 connected to each other in parallel, and three of third battery cells 113 connected to each other in parallel. In addition, the first battery cell 111, the second battery cell 112 and the third battery cell 113 are connected in series. Though the battery cells 111, 112 and 113 are illustrated as being connected in a 3 series 3 parallel (3S3P) manner, this particular arrangement is only an illustrative example for assisting understanding of the present inventive concept, however will not limit the present inventive concept to the connection type.

The conductive plates 121, 122, 123 and 124 connect adjacent battery cells 111, 112 and 113 in series. Particularly, the conductive plates 121, 122, 123 and 124 include a first conductive plate 121, a second conductive plate 122, a third conductive plate 123 and a fourth conductive plate 124. The first conductive plate 121 is connected to a minimum power supply, i.e., to an anode electrode of the first battery cell 111. In other words, the first conductive plate 121 is connected to the anode electrode of the three of the battery cells 111 in parallel. The second conductive plate 122 interconnects the first battery cell 111 and the second battery cell 112 in series. In addition, the second conductive plate 122 connects the cathode electrode of the first battery cells 111 in parallel and at the same time, connects the anode electrode of the second battery cells 112 in parallel. The third conductive plate 123 interconnects the second battery cell 112 and the third battery cell 113 in series. In addition, the third conductive plate 123 connects the cathode electrode of the second battery cells 112 in parallel and at the same time, connects the anode electrode of the third battery cells 113 in parallel. The fourth conductive plate 124 is connected to the maximum power supply B+, i.e., the cathode electrode of the third battery cell 113. In addition, the fourth conductive plate 124 connects to the cathode electrode of the third battery cells 113 in parallel. Meanwhile, the first to fourth conductive plates 121, 122, 123 and 124 include extrusion taps 121a, 122a, 123a and 124a with a specific length for an easy soldering to a wire in a following process. Of course, the number of the conductive plates 121, 122, 123 and 124 dependently increase on the number of the battery cells 111, 112 and 123 used.

The wire for minimum power supply 130 is soldered to the minimum power supply region of the first battery cell 111. That is, one terminal of the wire for minimum power supply 130 is soldered to the tap 121a of the conductive plate 121.

The wire for maximum power supply 140 is soldered to the maximum power supply region of the third battery cell 113. That is, one terminal of the wire for maximum power supply 140 is soldered to the tap 124a of the fourth conductive plate 124.

Two sensing wires 151 and 152 are provided as in the drawings. For the convenience of the explanation, a first sensing wire 151 and a second sensing wire 152 are differentiated. One terminal of the first sensing wire 151 is soldered to the tap 122a of the second conductive plate 122. In addition, one terminal of the second sensing wire 152 is soldered to the tap 123a of the third conductive plate 123. Similarly, the number of the sensing wires 151 and 152 increase according to the numbers of the battery cells and the number of conductive plates.

The rigid printed circuit board 300 is disposed at a side (or an upper portion) of the first, second, third battery cells 111, 112 and 113, as illustrated in the drawings. Here, the wire for minimum power supply 130 is connected to the B-terminal, the first sensing wire 151 is connected to the B1 terminal, the second sensing wire 152 is connected to the B2 terminal, and the wire for maximum power supply 140 is connected to the B+ terminal of the rigid printed circuit board 300. In the rigid printed circuit board 300, a plurality of battery protecting elements 330, such as a temperature sensor, a voltage sensor, a current sensor, a charge controlling switch, a discharge controlling switch, a microcomputer, etc. are installed.

The flexible printed circuit board 200 is soldered to one side of the rigid printed circuit board 300. Reference numeral 180 represents a pack case for installing all the constituting elements described above. In addition, pack terminals P+ and P−, which are connecting portions to an external charger or to an external set, are combined with the terminal portion of the flexible printed circuit board 200. Here, the flexible printed circuit board 200 may bend freely as compared to the rigid printed circuit board 300. Thus, the flexible printed circuit board 200 may bend in a specific direction from the rigid printed circuit board 300 to be combined with the pack terminals P+ and P−.

Here, the rigid printed circuit board 300 may be commonly formed by using an epoxy resin and/or a phenol resin as main materials and may include circuit patterns formed on the surface thereof. Since the epoxy resin and/or the phenol resin are relatively thick, heavy and rigid, the rigid printed circuit board 300 may not bend well. The basic structure of the rigid printed circuit board 300 is well known to a person in the art, and an explanation thereof will be omitted.

Flexible printed circuit board (FPCB) 200 is also called as flexible wire (FW) or flexible circuitry (FC), and is formed by using polyimide and/or polyethylene terephthalate (PET) as main materials, with circuit patterns arranged on the surface thereof. Polyimide and/or PET are relatively light, thin and flexible, and so the flexible printed circuit board 300 may bend well.

Hereinafter, the flexible printed circuit board will be referred to as a first circuit board, and the rigid printed circuit board will be referred to as a second circuit board for the convenience of explanation. The first circuit board includes a first circuit pattern and a first base insulating layer, and the second circuit board includes a second circuit pattern and a second insulating layer.

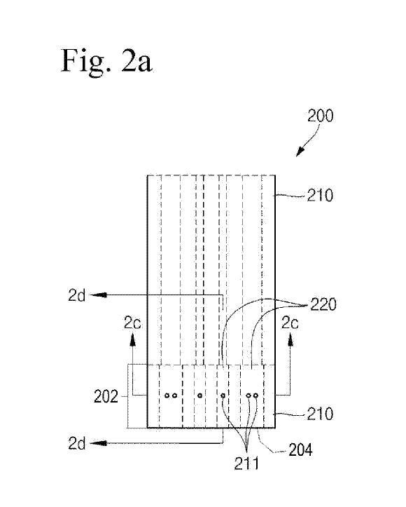

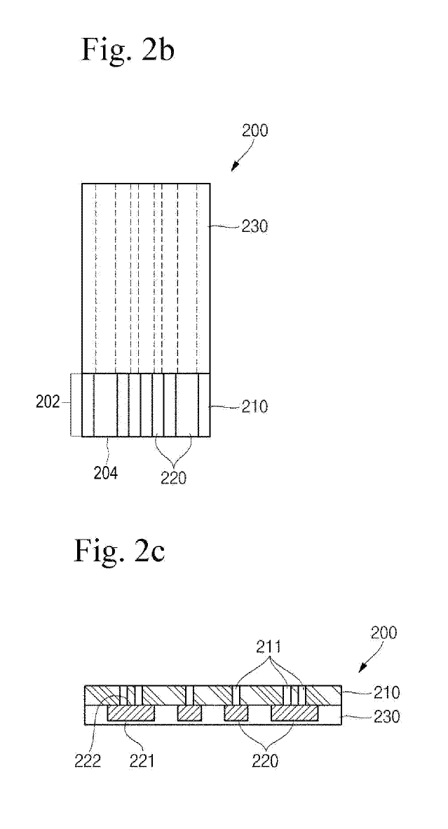

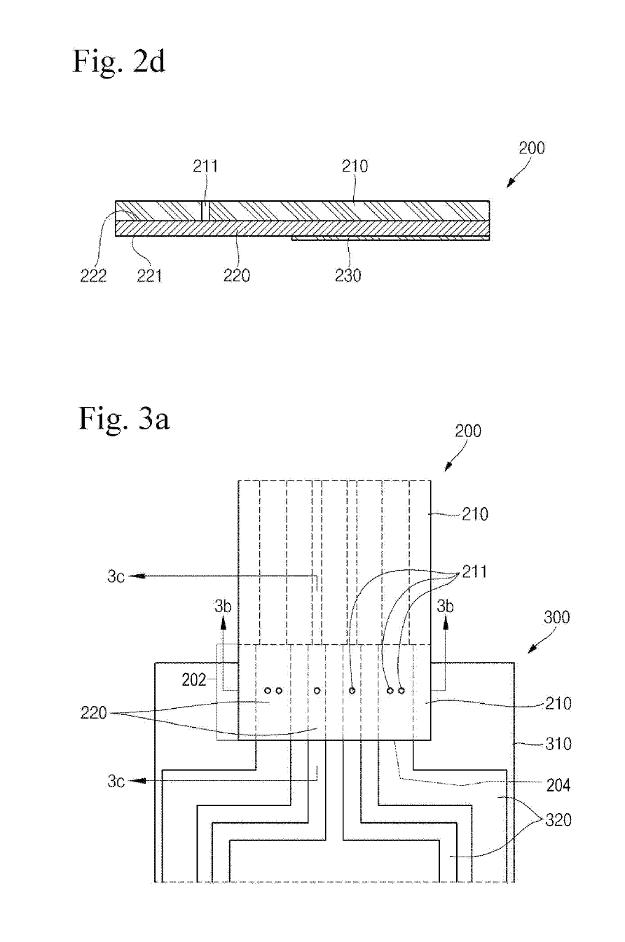

Turning now to FIGS. 2A to 2D, FIG. 2A illustrates a plan view of a circuit board according to an embodiment, FIG. 2B illustrates a bottom view, FIG. 2C illustrates a cross-sectional view of FIG. 2A cut along a line 2c-2c, and FIG. 2D illustrates a cross-sectional view of FIG. 2A cut along a line 2d-2d.

As illustrated in FIGS. 2A to 2D, a first circuit board 200 includes a first base insulating layer 210 having a at least one aperture 211, a first circuit pattern 220 and a first cover insulating layer 230.

The first base insulating layer 210 having at least one aperture 211, has a roughly flat panel shape and a thickness of about 0.5 μm to 500 μm, however the thickness value is not limited in exemplary embodiments, and may instead be changed according to the surroundings, the bending angle of the first circuit board 200, the required strength of the first circuit board 200, etc. In addition, the first base insulating layer 210 may be made out of polyimide, PET or an equivalent thereof, however the kinds of materials are not limited in exemplary embodiments. The first base insulating layer 210 is required to have good insulating property and a high glass transition temperature (Tg) so that there is only small dimensional deformation at a high temperature, good heat-resistance and good flexibility. In addition, the first base insulating layer 210 is required to have good chemical-resistance and resistance to moisture. Considering the above conditions, polyimide or PET are appropriate. Particularly, when the first base insulating layer 210 is polyimide, the glass transition temperature (Tg) thereof is greater than or equal to about 300° C. to 400° C., and the melting point (Tm) thereof is greater than or equal to about 500° C. to 700° C. Accordingly, the polyimide may sufficiently endure at the temperature range for soldering (about 150° C. to 300° C.) and may exhibit the above described physical and chemical properties. In contrast, PET has a glass transition temperature (Tg) greater than or equal to about 70° C. to 100° C., and the melting point (Tm) thereof greater than or equal to about 270° C. to 350° C. Because the glass transition temperature (Tg) and the melting point (Tm) for polyimide are higher than that of PET, the best embodiment is to use polyimide for the base insulating layer 210.

In addition, the apertures 211 may include one or more apertures 211 and are preferably through holes perforating first base insulating layer 210. The apertures 211 are preferably located within terminal end portion 202 of first circuit board 200 while being spaced-apart from a terminal edge 204 of first circuit board 210. The apertures 211 may be formed to have a circular shape, an elongated aperture shape, a quadrangular shape or a polygonal shape, however the aperture shape is not limited just to these in exemplary embodiments. The apertures 211 function to rapidly transmit the heat from the hot bar 600 to the first circuit pattern 220.

The first circuit pattern 220 is formed on the first base insulating layer 210 and has a thickness of about 30 μm to 100 μm, however the thickness is not limited to this range in accordance with exemplary embodiments and may be changed according to current, the desired bending angle of the first circuit board 200, the desired strength of the first circuit board 200, etc. The first circuit pattern 220 may be formed directly on the first base insulating layer 210 by one of casting, lamination, sputtering and an equivalent method thereof, however the method is not limited to the above described methods in the exemplary embodiments. The first circuit pattern 220 may instead be formed on the first base insulating layer 210 by forming an adhesive layer (not illustrated) and then laminating the first circuit pattern 220 on the adhesive layer. The first circuit pattern 220 may be made out of copper (Cu), aluminum (Al), gold (Au), silver (Ag), or a combination thereof or an equivalent thereof, without limitation.

The first circuit pattern 220 includes a first major surface 221, facing rigid printed circuit board 300 and the circuit pattern 320 formed thereon, and makes a contact with conductive connecting members 400 and 500, and a second major surface 222 facing the first major surface 221 and making a contact with the first base insulating layer 210. Accordingly, the second major surface 222 of the first circuit pattern 220 is exposed to an exterior through the apertures 211 formed in the first base insulating layer 210.

The first cover insulating layer 230 covers a portion of the first circuit pattern 220 and the first base insulating layer 210, at the same time. Here, a specific region among the first circuit pattern 220 may not be covered by the first cover insulating layer 230, but may be exposed directly to the exterior. Particularly, the first major surface 221 (i.e. a contacting region with conductive connecting members 400 and 500) and both side faces of the first circuit pattern 220 formed at one terminal of the first circuit board 200 may not be covered by the first cover insulating layer 230, but may be exposed to the exterior. The specific region of the first circuit pattern 220 not covered by the first cover insulating layer 230 but exposed to the exterior may be defined as a terminal or a lead. The exposed region of the first circuit pattern 220 not covered by the first cover insulating layer 230 may undergo an electroplating process using one of gold (Au), silver (Ag), nickel (Ni), palladium (Pd), an alloy thereof and an equivalent thereof, to prevent the oxidation of the first circuit pattern 220.

Meanwhile, the first cover insulating layer 230 is sometimes referred to as a coverlay and may be made out of one of polyimide, PET and an equivalent thereof, however the present invention is in no way limited to them. Particularly, when the first cover insulating layer 230 is PET, the glass transition temperature (Tg) thereof is greater than or equal to about 70° C. to 100° C., and the melting point (Tm) thereof is greater than or equal to about 270° C. to 350° C. The hot bar 600 may not substantially contact the first cover insulating layer 230. Thus, the first cover insulating layer 230 made of PET may not necessarily have as high a glass transition temperature (Tg) and melting point (Tm) as polyimide.

Although not illustrated in drawings, an additional reinforcing plate (not illustrated) may be attached on the surface of the first base insulating layer 210 or the first cover insulating layer 230 to reinforce the strength of the first circuit board 200. The reinforcing plate may be made out of one of polyimide, PET, a glass epoxy and an equivalent thereof, however will not be limited to these in exemplary embodiments. By including such a reinforcing plate, the flexibility of the first circuit board 200 may be decreased.

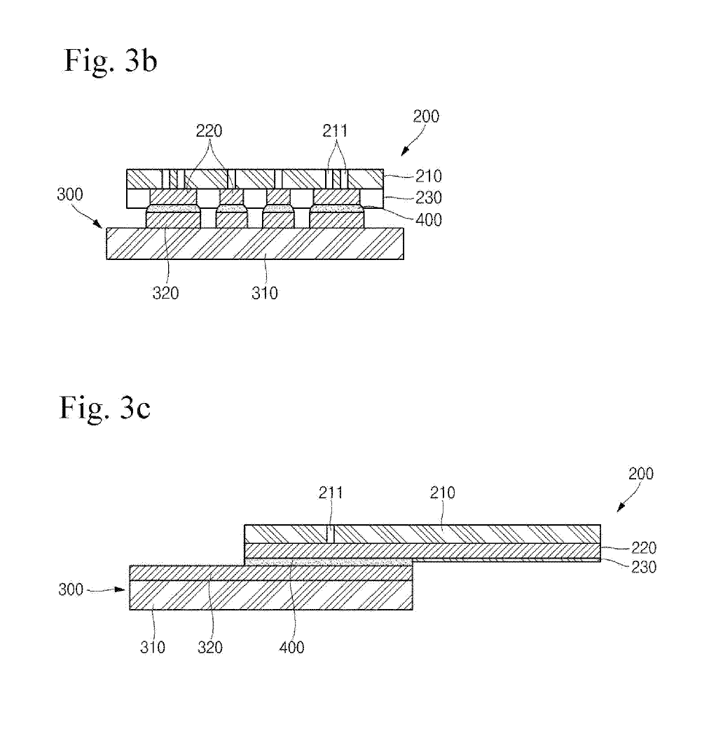

Turning now to FIGS. 3A to 3C, FIG. 3A illustrates a partially enlarged plan view on the connecting structure between circuit boards according to an embodiment, FIG. 3B illustrates a cross-sectional view of FIG. 3A cut along a line 3b-3b, and FIG. 3C illustrates a cross-sectional view of FIG. 3A cut along a line 3c-3d.

As illustrated in FIGS. 3A to 3C, a second circuit board 300 includes a second insulating layer 310 and a second circuit pattern 320 formed on the surface of the second insulating layer 310. Here, the first circuit board 200 may be defined as a flexible printed circuit board, and the second circuit board 300 may be defined as a rigid printed circuit board as described above.

The first circuit pattern 220 of the first circuit board 200 is electrically connected to the second circuit pattern 320 of the second circuit board 300 through the conductive connecting member 400. That is, the first major surface 221 of the first circuit pattern 220 is electrically connected to the second circuit pattern 320 by the conductive connecting member 400. Also, the first base insulating layer 210 is positioned at the second major surface 222 of the first circuit pattern 220, and at least one aperture 211 is formed at a region of the first base insulating layer 210 corresponding to the second major surface 222 of the first circuit pattern 220.

At least 1 to 10 apertures 211 may be formed for each of the circuit patterns, and the width of the aperture 211 may be smaller than the width of the circuit pattern. Accordingly, the conductive connecting member 400 does not flow into the apertures 211 even though the conductive connecting member 400 makes contact with the first base insulating layer 210 via the first circuit pattern 220.

Particularly, when the conductive connecting member 400 is solder, the solder of a liquid state may flow upward along both sides of the first circuit pattern 220 to make a contact with the first base insulating layer 210 during the soldering process. However, in accordance with exemplary embodiments as described above, the apertures 211 are located to correspond to the first circuit pattern 220 and have a width smaller than the width of the first circuit pattern 220 in a region corresponding to the second major surface 222 of the first circuit pattern 220. Thus, the solder flowed upward to the first base insulating layer 210 can not flow into the aperture 211 and does not reach the hot bar 600. As a result, the heat from the hot bar 600 during performing the soldering process may be easily transferred to the first circuit pattern 220 via the aperture 211.

Meanwhile, the width of the first circuit pattern 220 is preferably smaller than the width of the second circuit pattern 320. In this case, the extra amount of the solder during the soldering process remains on edge portions of the second circuit pattern 320 that co not correspond to the first circuit pattern 220, so that a short between neighboring solders may be prevented.

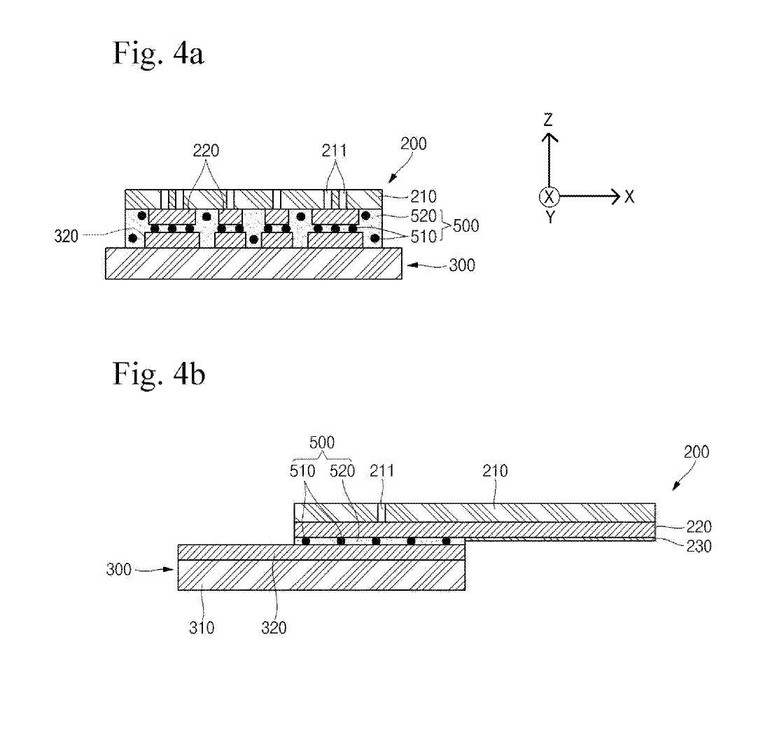

Turning now to FIGS. 4A and 4B, FIGS. 4A and 4B illustrate cross-sectional views of the connecting structure between circuit boards according to another embodiment. As illustrated in FIGS. 4A and 4B, one selected from anisotropic conductive films (ACF), Z-axis films (ZAF) and an equivalent thereof may be used as the conductive connecting member 500 in accordance with exemplary embodiments. Particularly, when the pitch of the circuit pattern is less than or equal to about 375 μm (about 15 mil), the connection between the first and second circuit substrates using solder may become difficult. That is, when the pitch of the circuit pattern is less than or equal to about 375 μm, short may be easily generated between neighboring solders.

In this case, ACF or ZAF is appropriate as the conductive connecting member 500. The ACF or ZAF has a filled type of conductive particles 510 in an insulating film 520. The ACF and ZAF may have a reflow temperature of 140° C. to 200° C., which is less than the 150° C. to 300° C. reflow temperature of solder 400.

First, ACF or ZAF is provided as the conductive connecting member 500 between the first circuit pattern 220 of the first circuit board 200 and the second circuit pattern 320 of the second circuit board 300. Then, the hot bar 600 pressurizes the first circuit board 200 while heating to laminate the first circuit board 200 on the second circuit board 300. That is, the conductive particles 510 of ACF or ZAF make an electric connection between the first circuit pattern 220 of the first circuit board 200 and the second circuit pattern 320 of the second circuit board 300. In addition, the first circuit board 200 and the second circuit board 300 may be physically connected due to the melting of the insulating film 520. Here, the conductive particles 510 of ACF or ZAF make an interconnection only in z-direction and do not make an interconnection in vertical x-direction or y-direction.

In this case, the heat of the hot bar 600 positioned on the first circuit board 200 may be easily transferred to the first circuit pattern 220 through the apertures 211 formed in the first base insulating layer 210, and the conductive particles 510 of ACF or ZAF or the insulating film 520 are prevented from entering the apertures 211.

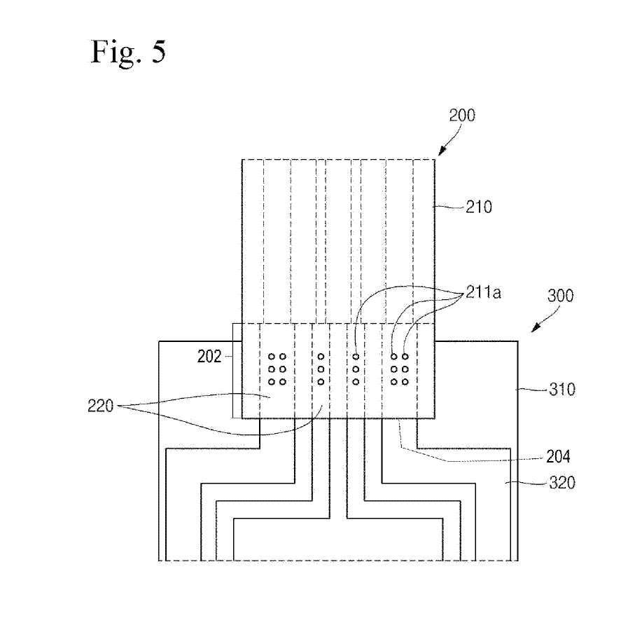

Turning now to FIGS. 5 to 8, FIGS. 5 to 8 illustrate partially enlarged plan views on the connecting structure portion between circuit boards according to other embodiment where the size, number, and design of the apertures is allowed to vary.

As illustrated in FIG. 5, the apertures 211a formed in the first base insulating layer 210 of the first circuit board 200 may be arranged along the longitudinal direction of the first circuit pattern 220. Particularly, one row of the apertures 211a may be formed in the first base insulating layer 210 corresponding to one of the first circuit patterns 220 having a relatively small width, while two rows of apertures 211a may be formed in the first base insulating layer 210 corresponding to one of the first circuit pattern 220 having a relatively large width.

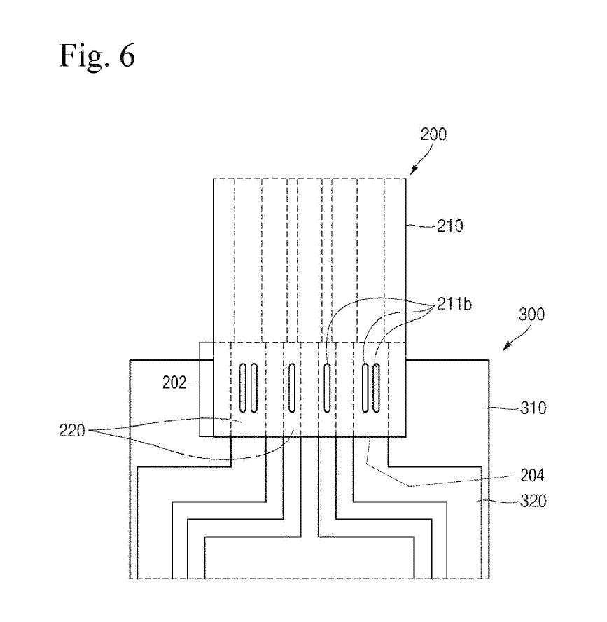

As illustrated in FIG. 6, the apertures 211b formed in the first base insulating layer 210 of the first circuit board 200 may instead have a long aperture shape along the longitudinal direction of the first circuit pattern 220. Also, one long aperture 211b may be formed in the first base insulating layer 210 corresponding to one of the first circuit patterns 220 having a relatively small width, while two long apertures 211b may be formed side by side in the first base insulating layer 210 corresponding to one of the first circuit patterns 220 having a relatively large width.

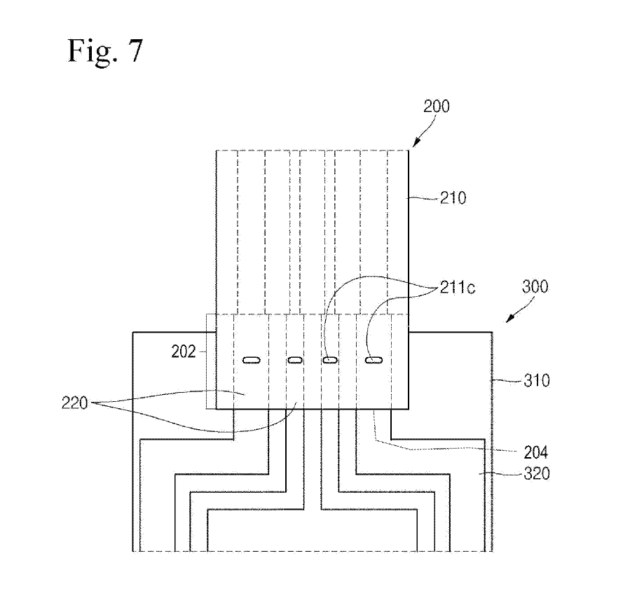

As illustrated in FIG. 7, the apertures 211c formed in the first base insulating layer 210 of the first circuit board 200 may have a long aperture shape along the lateral direction of the first circuit pattern 220, and about one aperture may be formed for one circuit board. As in other embodiments, the first circuit pattern 220 may be exposed to exterior only through the apertures 211c.

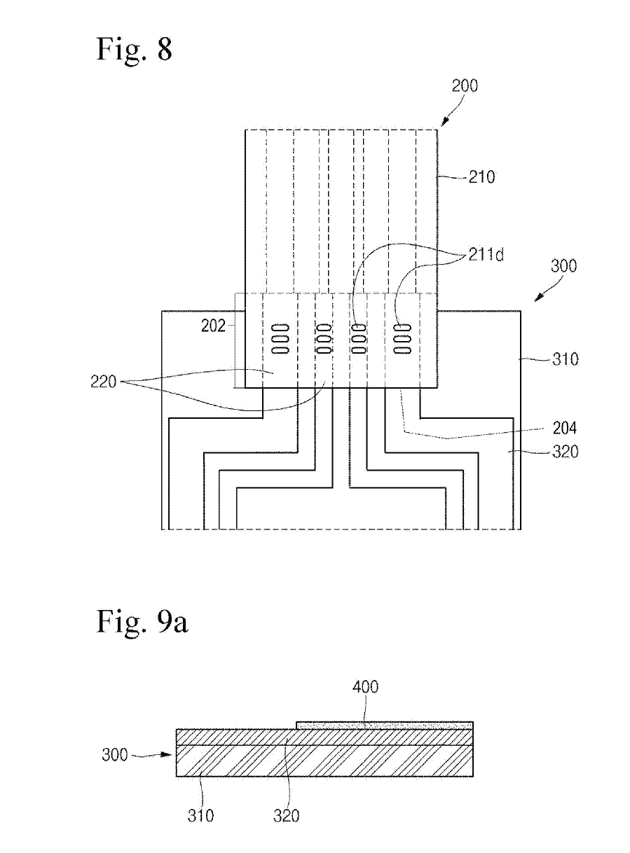

As illustrated in FIG. 8, the apertures 211d formed in the first base insulating layer 210 of the first circuit board 200 may be formed in plurality along the vertical direction of the longitudinal direction of the first circuit pattern 220 and may have a long aperture shape. In FIG. 8, three apertures 211d are formed for each of the circuit patterns. As always, the first circuit pattern 220 may be exposed to the exterior only through the aperture 211d.

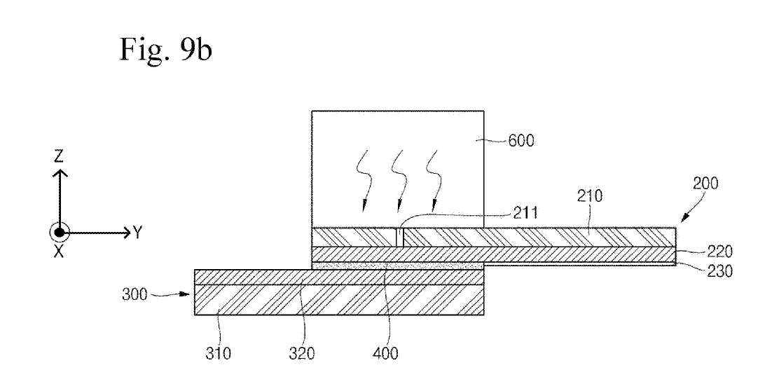

Turning now to FIGS. 9A and 9B, FIGS. 9A and 9B illustrates a schematic diagram for explaining a connecting method of circuit boards according to an embodiment of the present invention. First, as illustrated in FIG. 9A, a second circuit board 300 including a second circuit pattern 320 may be prepared, and a conductive connecting member 400 such as solder may be screen printed on the second circuit pattern 320.

Then, as illustrated in FIG. 9B, a first circuit board 200 including a first circuit pattern 220 is mounted on the second circuit board 300. As illustrated in FIG. 9B, the locations of the first circuit pattern 220 of the first circuit board 200 and the second circuit pattern 320 of the second circuit board 300 are aligned.

In this state, the first circuit board 200 is pressurized and heated using a hot bar 600 as illustrated in FIG. 9B. Then, the heat from the hot bar 600 may be efficiently transferred to the first circuit pattern 220 and the conductive connecting member 400 through apertures 211 formed in the first base insulating layer 210. Here, the temperature provided from the hot bar 600 may be about 150° C. to 300° C. Since the glass transition temperature (Tg) of the first base insulating layer 210 constituting the first circuit board 200 is greater than or equal to about 300° C. to 400° C., and the melting point (Tm) thereof is greater than or equal to about 500° C. to 700° C., the first base insulating layer 210 is not melted or deformed by the heat of from hot bar 600.

Meanwhile, the screen printed solder 400 between the first circuit pattern 220 and the second circuit pattern 320 may reflow as a liquid by the temperature provided by the hot bar 600. Since the reflow temperature of the solder 400 is about 150° C. to 300° C., solid state solder 400 may liquify.

Then, the hot bar 600 is separated from the first circuit board 200. The liquid state solder 400 may be cured to electrically and physically combine strongly the first circuit pattern 220 to the second circuit pattern 320.

Meanwhile, when ACF or ZAF is used as the conductive connecting member 500, the ACF or ZAF may be positioned between the first circuit board 200 and the second circuit board 300. As stated earlier, the locations of the first circuit pattern 220 of the first circuit board 200 and the second circuit pattern 320 of the second circuit board 300 may be aligned. Then, the first circuit board 200 may be pressurized and heated by using the hot bar 600, so that heat from the hot bar 600 may be transferred to the first circuit pattern 220, and ACF or ZAF 500 efficiently through the apertures 211 formed in the first base insulating layer 210.

As a result, the first circuit pattern 220 and the second circuit pattern 320 are arranged close to each other in the z-direction, and the conductive particles 510 interposed between the circuit patterns 220 and 320 may electrically interconnect the first circuit pattern 220 to the second circuit pattern 320. Since the conductive particles 510 do not make an electric connection in either of the x-direction and the y-direction, the neighboring patterns of the first circuit patterns 220 may maintain an electrically insulated state in the horizontal direction and neighboring patterns of the second circuit patterns 320 may maintain an electrically insulated state in the horizontal direction.

Accordingly, the hot bar 600 does not make a direct contact with the first circuit pattern 220 of the first circuit board 200 during the connecting of the first circuit board 200 to the second circuit board 300, and as a result, damage to the first circuit pattern 220 may be prevented and an electric short between ones of plurality of the first circuit patterns 220 due to the conductive connecting members 400 and 500 may be prevented.

In addition, since the first circuit pattern 220 of the first circuit board 200 does not make a contact with the hot bar 600 due to intervening first base insulating layer 210, the strength of the first circuit pattern 220 may be increased, and an epoxy coating process may be omitted.

In addition, since at least one aperture of 211, 211a, 211b, 211c and 211d is formed in the first base insulating layer 210 that makes a contact with the hot bar 600, an electrical connection may be accomplished without increasing the temperature of the hot bar 600. Thus, the lifetime of the hot bar 600 may be increased and the damage of the appearance of the first base insulating layer 210 may be prevented.

The explanation described above is only on example embodiment for accomplishing a circuit board connecting structure and a battery pack having the same according to exemplary embodiments. Accordingly, it will be understood by those of ordinary skill in the art that various changes in form and details may be made without departing from the spirit and scope of the present invention as set forth in the following claims.

[REFERENCE NUMERALS]

| | |
|---|---|
| 111, 112, 113 battery cells | 121, 122, 123, 124 conductive |
| | plates |
| 121a, 122a, 123a, 124a extrusion tap | 130, 140 min and max power wire |
| 151, 152 sensing wires | 180 pack case |
| P−, P+ pack terminals | B−, B+ min and max power supply |
| 200; first circuit board | 202 terminal end |
| 204 terminal edge | 210; first base insulating layer |
| 211; aperture | 220; first circuit pattern |
| 230; first cover insulating layer | 300; second circuit board |
| 310; second insulating layer | 320; second circuit pattern |
| 400; conductive connecting member | 500; conductive connecting |
| | member |
| 510; conductive particle | 520; insulating film |
| 600; hot bar | |

What is claimed is:

1. A battery pack, comprising:
a first printed circuit board including a first circuit pattern having first major surface opposite a second major surface, the second major surface being covered by a first base insulating layer and a portion of the first major surface being covered by a first cover insulating layer, the first base insulating layer being perforated by at least one aperture, each of the at least one aperture being entirely covered by the first circuit pattern;
a second printed circuit board having one side attached to a first end of the first printed circuit board by a conductive connecting member;
a plurality of battery cells arranged on the second printed circuit board, the plurality of battery cells being electrically interconnected together;
a pack case enclosing the first printed circuit board, the second printed circuit board and the battery cells; and
pack terminals arranged on an outside of the pack case and being attached to a second and opposite end of the first printed circuit board.

2. The battery pack of claim 1, the first base insulating layer having a glass transition temperature (Tg) that is greater than a reflow temperature of the conductive connecting member.

3. The battery pack of claim 1, the first base insulating layer being comprised of an electrically insulating material having a glass transition temperature (Tg) of at least 300° C.

4. The battery pack of claim 3, the conductive connecting member being a solder having a reflow temperature of less than 300° C.

5. The battery pack of claim 3, the conductive connecting member being selected from a group consisting of an anisotropic conductive film (ACF) and a Z-axis film (ZAF).

6. The battery pack of claim 3, wherein the first printed circuit board is a flexible printed circuit board that can bend freely as compared to the second printed circuit board.

7. The battery pack of claim 1, further comprising a second circuit pattern arranged on the second printed circuit board, the second circuit pattern being aligned with the first circuit pattern.

8. The battery pack of claim 7, a width of the second circuit pattern being greater than a width of the first circuit pattern.

9. The battery pack of claim 3, wherein the first end of the first printed circuit board that is attached to the second printed circuit board is absent of the first cover insulating layer.

10. A printed circuit board (PCB), comprising:
a base insulating layer perforated by at least one aperture;
a circuit pattern arranged on the base insulating layer and covering each of the at least one aperture; and
a cover insulating layer arranged on the circuit pattern and on the base insulating film.

11. The PCB of claim 10, wherein a terminal end of the PCB is absent of the cover insulating layer.

12. The PCB of claim 10, wherein the base insulating layer is comprised of a material selected from a group consisting of polyimide and polyethylene terephthalate (PET).

13. The PCB of claim 10, wherein the cover insulating layer is comprised of a material selected from a group consisting of polyimide and polyethylene terephthalate (PET).

14. The PCB of claim 10, wherein the printed circuit board is a flexible printed circuit board that can bend freely.

15. The PCB of claim 10, wherein the base insulating layer is comprised of a material having a glass transition temperature (Tg) of at least 300° C. and a melting point (Tm) of at least 500° C.

16. The PCB of claim 10, wherein the cover insulating layer is comprised of a material having a glass transition temperature (Tg) of at least 70° C. and a melting point (Tm) of at least 270° C.

17. The PCB of claim 10, wherein each of the at least one aperture is elongated in a lengthwise direction of the circuit pattern.

18. The PCB of claim 10, wherein each of the at least one aperture is elongated in a widthwise direction of the circuit pattern.

19. A method of connecting a first printed circuit board to a second printed circuit board, comprising:
preparing the first printed circuit board by arranging a first cover insulating layer onto a portion of a first surface of a first circuit pattern, and arranging a first base insulating layer onto a second and opposite surface of the first circuit pattern, the first base insulating layer being perforated by at least one aperture, the first circuit pattern covering each of the at least one aperture;
preparing the second printed circuit board by arranging a second circuit pattern onto a second base insulating layer;
applying a conductive connecting member onto the second circuit pattern by screen printing;
aligning the first circuit pattern with the second circuit pattern by mounting a terminal end portion of the first printed circuit board onto one side of the second printed circuit board;
reflowing said conductive connecting member by placing a hot iron onto a portion of the first base insulating layer corresponding to the terminal end portion of the first printed circuit board, the at least one aperture to rapidly and efficiently transmit heat from the hot iron to the first circuit pattern and to the conductive connecting member; and
allowing the conductive connecting member to cure by separating the hot iron from the first base insulating layer.

20. The method of claim 19, wherein the first circuit pattern is spaced-apart from the hot iron by the first base insulating layer upon said placing of the hot iron onto the portion of the first base insulating layer.
